(19) United States
(12) Patent Application Publication
(10) Pub. No.: US 2018/0061811 A1
(43) Pub. Date: Mar. 1, 2018

(54) SEMICONDUCTOR PACKAGE AND MANUFACTURING METHOD THEREOF

(71) Applicant: ChipMOS Technologies Inc., Hsinchu (TW)

(72) Inventors: Geng-Shin Shen, Hsinchu (TW); Ching-Chen Tu, Hsinchu (TW); Tzu-Sheng Wu, Hsinchu (TW); Chun-Chen Lin, Hsinchu (TW); Hui-Wen Yeh, Hsinchu (TW)

(73) Assignee: ChipMOS Technologies Inc., Hsinchu (TW)

(21) Appl. No.: 15/373,494

(22) Filed: Dec. 9, 2016

(30) Foreign Application Priority Data
Aug. 30, 2016 (TW) 105127804

(51) Int. Cl. H01L 25/065; H01L 23/00; H01L 23/31; H01L 25/00; H01L 21/56; H01L 21/78

(52) U.S. Cl. CPC H01L 25/0657; H01L 24/16; H01L 23/3185; H01L 25/50; H01L 21/563; H01L 2224/16145; H01L 2225/06513; H01L 2225/06548; H01L 2225/06558; H01L 2225/06586; H01L 21/78

(57) ABSTRACT

A semiconductor package includes a first chip, a second chip, a plurality of first conductive bumps, a plurality of second conductive bumps and an underfill. The first chip includes a first active surface having a chip bonding zone, a plurality of first inner pads in the chip bonding zone and a plurality of first outer pads out of the chip bonding zone. The second chip is flipped on the chip bonding zone. The first conductive bumps are disposed on the first outer pads. The second conductive bumps are disposed between the first inner pads of the first chip and a plurality of second pads of the second chip. The underfill is disposed on the first active surface and covers the second conductive bumps, at least a part of each second chip lateral and at least a part of each first conductive bump. Multiple semiconductor package manufacturing methods are further provided.

### CROSS-REFERENCE TO RELATED APPLICATION

This application claims the priority benefit of Taiwan application serial no. 105127804, filed on Aug. 30, 2016. The entirety of the above-mentioned patent application is hereby incorporated by reference herein and made a part of this specification.

### BACKGROUND OF THE INVENTION

### 1. Field of the Invention

The invention generally relates to a package and a manufacturing method thereof, and more particularly, to a semiconductor package and a manufacturing method thereof.

### 2. Description of Related Art

With rapid advance in technologies, integrated circuits (ICs) have been extensively used in our daily lives. Typically, IC manufacturing can be roughly classified into three main stages: a silicon wafer fabrication stage, an IC fabrication stage, and an IC package stage.

In current package structure, flipping a small size chip on a large size chip and electrically connecting the two via a conductive pillar therebetween is a common package method. However, in the current multi-chip package, side faces of the small size chip are exposed and a chip backside is also often exposed, thereby causing a chipping rate of the small size chip in the multi-chip package to be higher.

### SUMMARY OF THE INVENTION

The invention provides a semiconductor package which has a lower chipping rate.

The invention provides multiple semiconductor package manufacturing methods which can produce the aforementioned semiconductor package.

A semiconductor package of the invention includes a first chip, a second chip, a plurality of first conductive bumps, a plurality of second conductive bumps and an underfill. The first chip includes a first active surface, wherein the first active surface includes a chip bonding zone, a plurality of first inner pads in the chip bonding zone and a plurality of first outer pads out of the chip bonding zone. The second chip is flipped on the chip bonding zone of the first chip and includes a second active surface and a plurality of second chip side faces connected to the second active surface, wherein the second active surface includes a plurality of second pads. The first conductive bumps are disposed on the first outer pads. The second conductive bumps are located between the first inner pads and the second pads, each of the first inner pads is electrically connected with the corresponding second pad via the corresponding second conductive bump. The underfill is disposed on the first active surface and covers the second conductive bumps, at least a part of each of the second chip side faces and at least a part of each of the first conductive bumps.

In one embodiment of the invention, the underfill includes a molded unclean (MUF), and the molded underfill covers all the second chip side faces.

In one embodiment of the invention, the second chip further includes a chip backside opposite to the second active surface, and the chip backside is covered by the molded underfill or the chip backside is exposed by the molded underfill.

In one embodiment of the invention, the semiconductor package further includes a plurality of weldments, the first conductive bumps are exposed out of the molded underfill, the weldments are disposed on the molded underfill and connected to the first conductive bumps, wherein each of the weldments comprises a solder ball, a solder cap or a solder layer.

In one embodiment of the invention, a height of the first conductive bumps is greater than or equal to a distance from the chip backside of the second chip to the first inner pads.

In one embodiment of the invention, the semiconductor package further includes a plurality of solder balls and a protective layer, the solder balls are disposed on the first conductive bumps, each of the first conductive bumps is an under bump metal (UBM) layer, and the molded underfill covers a part of each of the solder balls. The protective layer is disposed on the first active surface of the first chip, the protective layer includes an opening at least corresponding to the chip bonding zone, and the first inner pads and the first outer pads are exposed out of the protective layer.

In one embodiment of the invention, the second chip further includes a chip backside opposite to the second active surface, a distance from the chip backside of the second chip to the first inner pads is greater than a height of each of the first conductive bumps, and the height of each of the first conductive bumps is greater than a height of each of the second conductive bumps.

In one embodiment of the invention, each of the solder balls protrudes out of the molded underfill by a height ranging from 0.5 to 0.8 times of a height of the solder ball.

In one embodiment of the invention, the semiconductor package further includes a protective layer disposed on the first active surface of the first chip, the first inner pads and the first outer pads are exposed out of the protective layer, the protective layer includes an opening corresponding to the chip bonding zone, the underfill includes an inner underfill, the inner underfill the inner underfill is located between the chip bonding zone of the first chip and the second chip, and the molded underfill covers the inner underfill.

In one embodiment of the invention, the semiconductor package further includes a protective layer disposed in a region outside of a virtual area surrounded by the first outer pads on the first active surface of the first chip, and the underfill covers a part of each of the second chip side faces of the second chip and a part of each of the first conductive bumps, and each of the first conductive bumps is a solder ball.

A semiconductor package manufacturing method of the invention includes: providing a wafer including a plurality of first chips arranged in an array, wherein each of the first chips includes a first active surface, and the first active surface includes a chip bonding zone, a plurality of first inner pads in the chip bonding zone and a plurality of first outer pads out of the chip bonding zone; disposing a plurality of the first conductive bumps on the first outer pads; flipping a plurality of second chips on the chip bonding zones of the first chip, wherein each of the second chips includes a second active surface and a plurality of second chip side faces connected to the second active surface, each of the second active surfaces includes a plurality of second pads, each of the second active surfaces faces towards the first active surface, and the second pads are electrically connected to the first inner pads; performing a molded underfill process to form a molded underfill on the first active surface, wherein the molded underfill covers the first conductive bumps and the second chips; performing a grinding process to the molded underfill to expose the first conductive bumps; disposing a plurality of weldments on the first conductive bumps to form a plurality of semiconductor packages; and performing a cutting process to separate the semiconductor packages from each other.

In one embodiment of the invention, each of the weldments includes a solder ball, a solder cap or a solder layer.

In one embodiment of the invention, the second chip further includes a chip backside opposite to the second active surface, and after performing the grinding process to the molded underfill, the chip backside is exposed out of the molded underfill.

In one embodiment of the invention, after flipping on the second chip and before preforming the molded underfill process, further includes: disposing a protective layer on the first active surface of the first chip, the first inner pads and the first outer pads being exposed out of the protective layer, and the protective layer including an opening corresponding to the chip bonding zone; and disposing an inner underfill between the chip bonding zone of the first chip and the second chip, wherein, after performing the molded underfill process, the molded underfill covers the inner underfill.

A semiconductor package manufacturing method of the invention includes: providing a wafer comprising a plurality of first chips arranged in an array, wherein each of the first chips first chip includes a first active surface, the first active surface includes a chip bonding zone, a plurality of first inner pads in the chip bonding zone and a plurality of first outer pads out of the chip bonding zone, the first active surface is disposed with a protective layer thereon, the protective layer includes an opening at least corresponding to the chip bonding zone, and the first inner pads and the first outer pads are exposed out of the protective layer; disposing a plurality of solder balls on the first outer pads to electrically connect with the first outer pads; flipping a plurality of second chips on the chip bonding zones of the first chips, wherein each of the second chips includes a second active surface and a plurality of second chip side faces connected to the second active surface, each of the second active surfaces includes a plurality of second pads, each of the second active surface faces towards the first active surface, and the second pads are electrically connected to the first inner pads; performing a molded underfill process to form a molded underfill on the first active surface, wherein the molded underfill covers the second chip and a part of each of the solder balls to complete a plurality of semiconductor packages; and performing a cutting process to separate the semiconductor packages from each other.

In one embodiment of the invention, the solder balls and the first outer pads have a plurality of under bump metal (UBM) layers disposed therebetween, and the molded underfill covers the under bump metal layers.

In one embodiment of the invention, the second chip further includes a chip backside opposite to the second active surface, a distance from the chip backside of the second chip to the first inner pads is greater than a height of each of the under bump metal layers, and the height of each of the under bump metal layers is greater than a distance between the first active surface and the second active surface.

In one embodiment of the invention, each of the solder balls protrudes out of the molded underfill by a height ranging from 0.5 to 0.8 times of a height of the solder ball.

In one embodiment of the invention, after flipping on the second chip and before performing the molded underfill process, further includes: disposing an inner underfill between the chip bonding zone of the first chip and the second chip, wherein, after performing the molded underfill process, the molded underfill covers the inner underfill.

In one embodiment of the invention, is located in a region outside of a virtual area surrounded by the first outer pads on the first active surface of the first chip, the molded underfill covers a part of each of the second chip side faces of the second chip and a part of each of the first conductive bumps, and each of the first conductive bumps is a solder ball.

In view of the above, the underfill of the semiconductor package of the invention covers the second conductive bumps, at least a part of each of the second chip side faces and at least a part of each of the first conductive bumps to increase an overall structural strength. Therefore, the semiconductor package of the invention can have the lower chipping rate. In addition, the invention further provides multiple semiconductor package manufacturing methods for producing the aforementioned semiconductor package.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are schematic manufacturing flow diagrams of a semiconductor package according to an embodiment of the invention.

FIG. 1G to FIG. 1J are schematic diagrams illustrating a plurality of semiconductor packages according to other embodiments of the invention.

FIG. 2A to FIG. 2E are schematic manufacturing flow diagrams of a semiconductor package according to another embodiment of the invention.

FIG. 2F to FIG. 2G are schematic diagrams of a plurality of semiconductor packages according to other embodiments of the invention.

FIG. 3 is a schematic diagram of a semiconductor package according to an embodiment of the invention.

### DESCRIPTION OF THE EMBODIMENTS

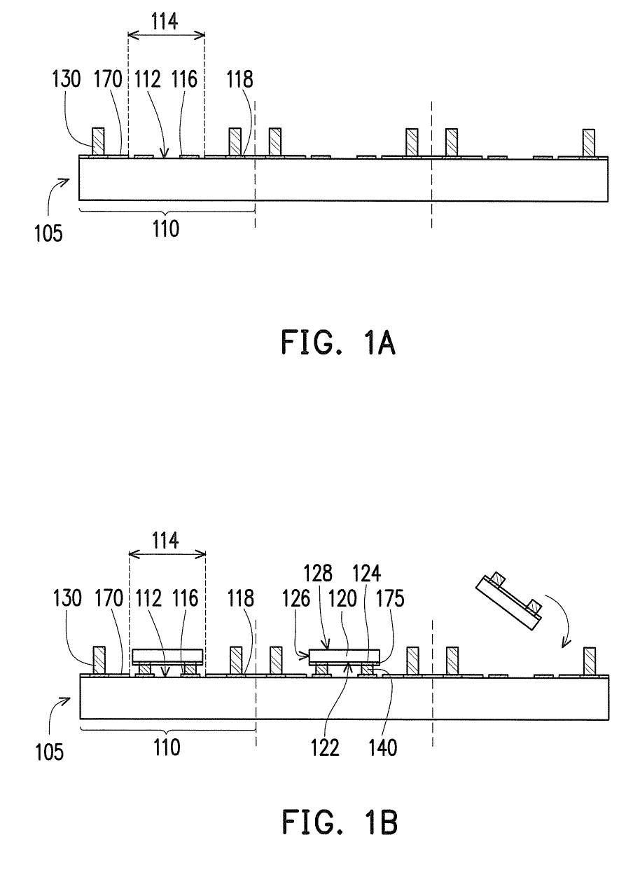

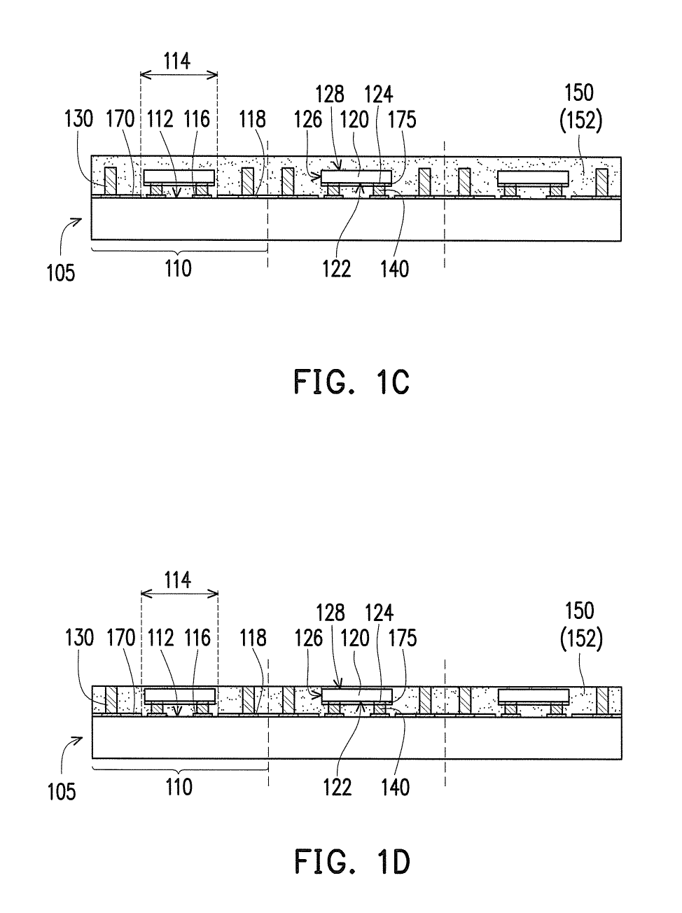

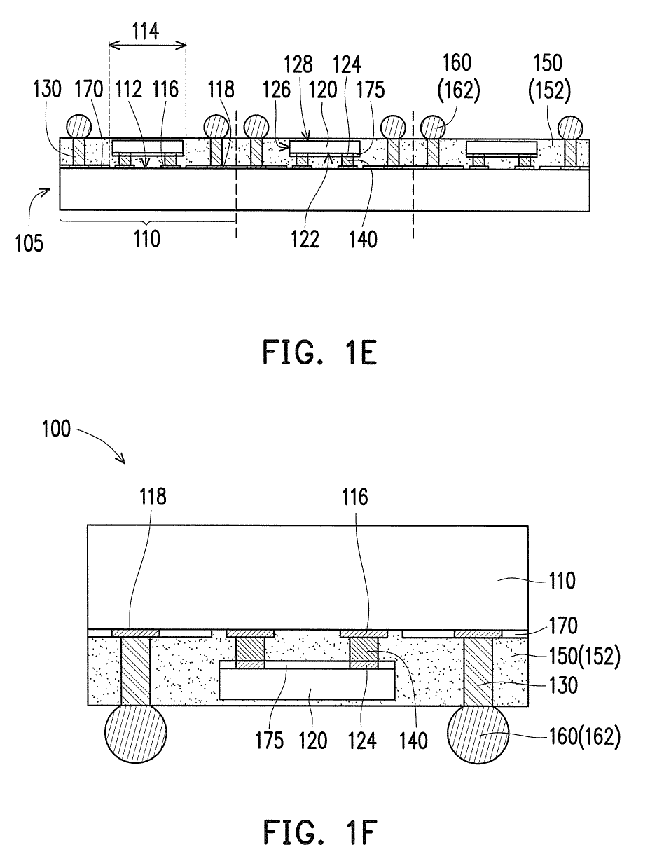

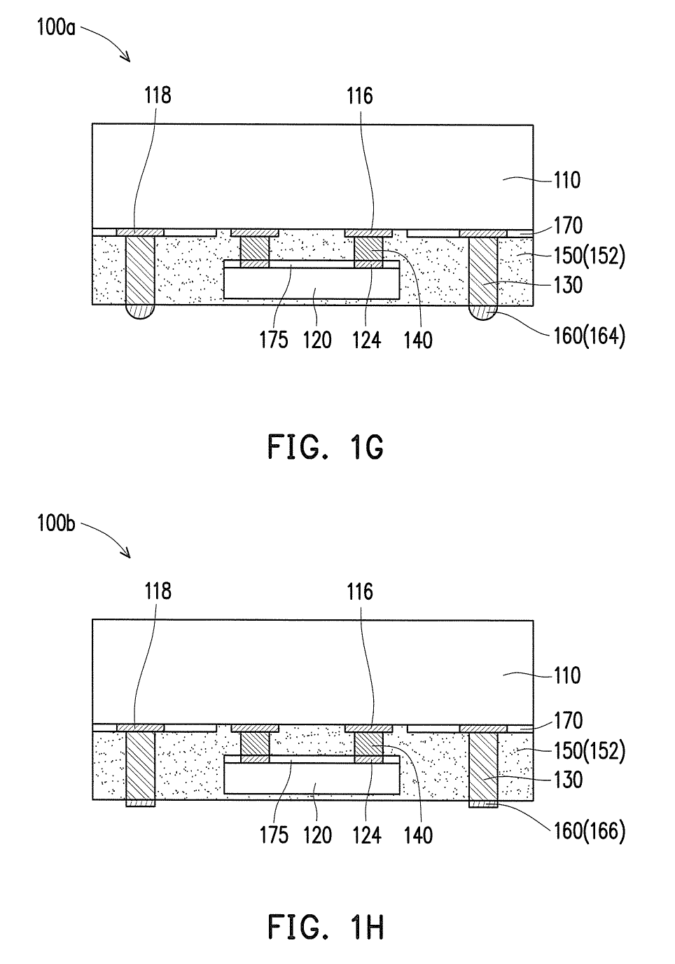

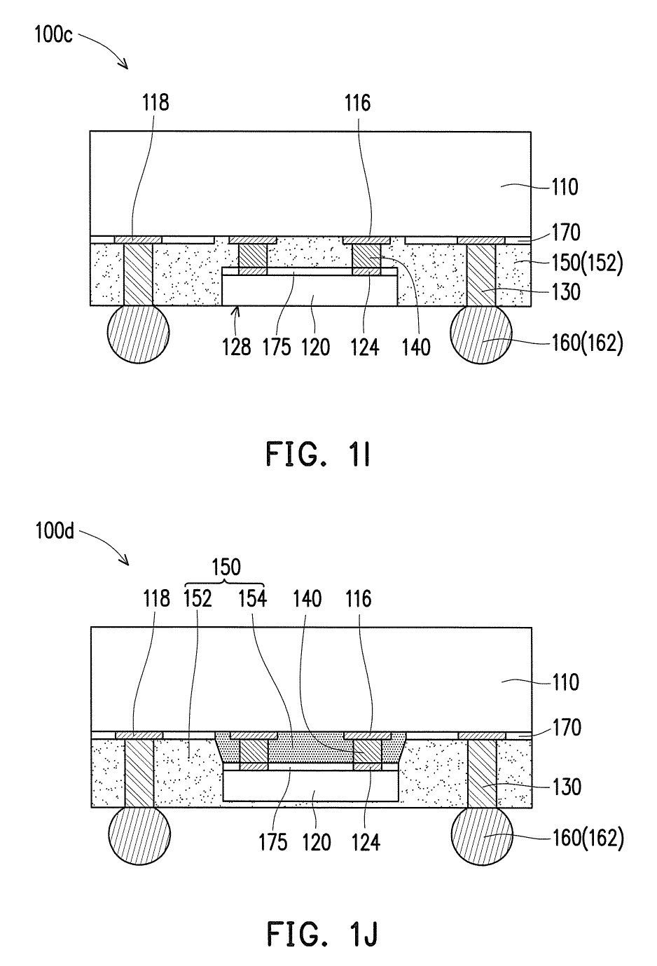

FIG. 1A to FIG. 1F are schematic manufacturing flow diagrams of a semiconductor package 100 according to an embodiment of the invention. A manufacturing method of the semiconductor package 100 of the present embodiment includes the following steps. Firstly, referring to FIG. 1A, a wafer 105 is provided, and the wafer 105 includes a plurality of first chips 110 arranged in an array. FIG. 1A schematically illustrates only one of the cross-sections of the wafer 105, and this cross-section schematically shows three first chips 110 arranged in a roll, but indeed, the number of the first chips 110 of the wafer 105 are not limited thereto. In the present embodiment, each of the first chips 110 includes a first active surface 112, and the first active surface 112 includes a chip bonding zone 114, a plurality of first inner pads 116 in the chip bonding zone 114 and a plurality of first outer pads 118 out of the chip bonding zone 114.

At the beginning of the manufacturing process, a step of incoming clean can be selectively performed to the wafer 105, so as to remove surface dirt on the first chips 110 by means of, for example, high pressure water jet cleaning. Certainly, in other embodiments, the incoming clean can also be selected to not perform to the wafer 105.

Next, a protective layer 170 is disposed on the first active surfaces 112 of the first chips 110, the first inner pads 116 and the first outer pads 118 are exposed out of the protective layer 170, and the protective layer 170 includes an opening corresponding to the chip bonding zones 114. In detail, the first chips 110 can be firstly coated with the protective layer 170, and a material of the protective layer 170 can be a typical photosensitive resist material, such as polyimide (PI), polybenzoxazole (PBO), nenzocyclobuten (BCB), acrylates or epoxy, etc. The protective layer 170 is further masked with a photomask (not shown) and underwent an exposure procedure, wherein a pattern of the photomask is corresponded to a pattern of the first chips 110 that is intended to be exposed. Afterwards, a develop procedure is performed to use a developer to dissolve and remove the unexposed protective layer 170. Next, the unremoved protective layer 170 is cured by means of heating, and a surface treatment is performed to the cured protective layer 170 through using oxygen plasma, nitrogen plasma or nitrogen-oxygen mixture plasma, so as to complete the protective layer 170. Further, a plurality of first conductive bumps 130 are disposed on the first outer pads 118. A method of disposing the first conductive bumps 130 may include bump placement, electroplating or printing with or without a reflow process. In the present embodiment, a material of the first conductive bumps 130 includes a single metal element or an alloy which may include gold, silver, copper, tin, nickel or an alloy thereof. In the drawings of the invention, the first conductive bumps 130 are, for example, columnar-shaped; however, an external shape of the first conductive bumps 130 may also be ball-shaped, which is not limited thereto, and a selected material thereof may also be formed by electroplating a single metal material, or two or more than two types of metal materials. For instance, feasible conductive bumps of the invention may include copper pillars being formed with a tin-silver solder layer thereon, copper pillars being formed with tin-silver solder caps thereon, copper pillars being covered with a layer nickel and gold, copper pillars being covered with a layer of gold, or so forth.

Further, referring to FIG. 1B, a plurality of second chips 120 with smaller size are flipped on the chip bonding zones 114 of the first chips 110. In the present embodiment, each of the second chips 120 includes a second active surface 122, a plurality of second chip side faces 126 connected to the second active surface 122, a chip backside 128 opposite to the second active surface 122 and a protective layer 175 disposed on the second active surface 122. Each of the second active surfaces 122 includes a plurality of second pads 124, the second pads 124 are exposed out of the protective layer 175, each of the second active surfaces 122 faces towards the first active surface 112, and the second pads 124 are electrically connected to the first inner pads 116 via a plurality of second conductive bumps 140 so as to bond the first chips 110 with the second chips 120 and to produce electric connections. A method of bonding may include reflow, thermal compression bonding (TCB), thermal eutectic bonding, thermal ultrasonic bonding or so forth. In the present embodiment, a height of the first conductive bumps 130 is greater than a height of the second conductive bumps 140. Further speaking, the height of the first conductive bumps 130 is greater than a total height of the second conductive bumps 140 and the second chips 120.

Similarly, in the present embodiment, a material of the second conductive bumps 140 includes a single metal element or alloy which may include gold, silver, copper, tin, nickel or an alloy thereof In the drawings of the invention, the second conductive bumps 140 are, for example, columnar-shaped; however, an external shape of the second conductive bumps 140 may also be ball-shaped, which is not limited thereto, and a selected material thereof may also be formed by electroplating a single metal material, or two or more than two types of metal materials. For instance, feasible conductive bumps of the invention may include copper pillars being formed with a tin-silver solder layer thereon, copper pillars being formed with tin-silver solder caps thereon, copper pillars being covered with a layer nickel and gold, copper pillars being covered with a layer of gold, or so forth.

Next, referring to FIG. 1C, a molded underfill process is performed to form an underfill 150 on the first active surface 112 of the first chip 110. In the present embodiment, the underfill 150 is, for example, a molded underfill 152, wherein the molded underfill 152 covers the first conductive bumps 130 and the second chips 120. In the present embodiment, the material of the molded underfill 152 is, for example, composed of epoxy resin material, thermosetting material, thermoplastic material, UV curable material, or analogues thereof The thermosetting material may include a benzene type, acid anhydride type, or amine type hardener and an acrylic polymer additive. However, the material of the molded underfill 152 is not limited thereto. The molded underfill 152 may be used to provide a fixing effect between the first chips 110 and the second chips 120, and can provide effects, such as cushioning, anti-moisture, dustproof and so forth, to enhance the reliability of packaging.

Further, referring to FIG. 1D, a grinding process is performed to the underfill 150 (molded underfill 152) to expose the first conductive bumps 130. In the present embodiment, a height of the underfill 150 (the molded underfill 152) is reduced by performing mechanical grinding on the underfill 150 (the molded underfill 152). Since a height of the first conductive bumps 130 is greater than a distance from the chip backsides 128 of the second chips 120 to the first active surface 112, when the first conductive bumps 130 are exposed, the chip backsides 128 of the second chips 120 are still covered by the underfill 150 (the molded underfill 152).

Next, referring to FIG. 1E, a plurality of weldments 160 are disposed on the first conductive bumps 130 to form a plurality of semiconductor packages 100. In the present embodiment, the weldments 160 are, for example, solder balls 162, but the type of the weldments 160 is not limited thereto. Finally, a cutting process is performed to separate the semiconductor packages 100 from each other so as to form the semiconductor package 100 as shown in FIG. 1F.

Referring to FIG. 1F, the semiconductor package 100 of the present embodiment includes a first chip 110, a second chip 120, a plurality of first conductive bumps 130, a plurality of second conductive bumps 140, an underfill 150, a plurality of weldments 160 and a protective layer 170. The first chip 110 includes a first active surface 112, wherein the first active surface 112 includes a chip bonding zone 114, a plurality of first inner pads 116 in the chip bonding zone 114 and a plurality of first outer pads 118 out of the chip bonding zone 114. The protective layer 170 is disposed on the first active surface 112 of the first chip 110, the first inner pads 116 and the first outer pads 118 are exposed out of the protective layer 170, and the protective layer 170 includes an opening corresponding to the chip bonding zone 114.

The second chip 120 is flipped on the chip bonding zone 114 of the first chip 110, and includes a second active surface 122 and a plurality of second chip side faces 126 connected to the second active surface 122, wherein the second active surface 122 includes a plurality of second pads 124. The first conductive bumps 130 are disposed on the first outer pads 118. The second conductive bumps 140 are located between the first inner pads 116 and the second pads 124, and each of the first inner pads 116 is electrically connected with the corresponding pad 124 via the corresponding second conductive bump 140.

The underfill 150 is located on the first active surface 112 and covers the second conductive bumps 140, at least a part of each of the second chip side faces 126 and at least a part of each of the first conductive bumps 130. More specifically, the underfill 150 includes a molded underfill 152 (MUF), and the molded underfill 152 covers all of the second chip side faces 126.

In the present embodiment, a height of the first conductive bumps 130 is greater than or equal to a distance from the chip backside 128 of the second chip 120 to the first inner pads 116, the first conductive bumps 130 are exposed out of the molded underfill 152, the second chip 120 further includes a chip backside 128 opposite to the second active surface 122, and the chip backside 128 is covered by the molded underfill 152. The weldments 160 are disposed on the molded underfill 152 and connected to the first conductive bumps 130, and the weldments 160 is, for example, solder balls 162.

The semiconductor package 100 of the present embodiment covers the second conductive bumps 140, at least a part of each of the second chip side faces 126 and at least a part of each of the first conductive bumps 130 via the underfill 150 (the molded underfill 152), and thus the overall structure strength of the semiconductor package 100 can be effectively increased, thereby enabling the semiconductor package 100 of the present embodiment to have a lower chipping rate.

It is to be explained that, although, in the present embodiment, the second chip 120 is flipped on the chip bonding zone 114 after firstly forming the first conductive bumps 130 on the first outer pads 118, in other embodiment, the second chip 120 may also be firstly flipped on the chip bonding zone 114 to enable the second conductive bumps 140 to be connected to the first inner pads 116 before forming the first conductive bumps 130 on the first outer pads 118. The sequence of the manufacturing processes can be adjusted based on the requirements.

It is to be noted that, in a not shown embodiment, the semiconductor package 100 that has been singled out may also be electrically connected to a circuit board (not shown) via the first conductive bumps 130 so as to electrically connect the first chip 110, the second chip 120 and the circuit board. In the aforementioned structure, the second chip 120 and the second conductive bumps 140 are located between the circuit board and the first chip 110.

The above merely disclosed one of the forms of the semiconductor package 100, and other forms of the semiconductor packages 100a, 100b, 100c and 100d are further disclosed in below. In order to facilitate understanding, in the following embodiments, components identical or similar to the ones described in the previous embodiment are presented with the same or similar component notations, and will not be repeated herein. FIG. 1G to FIG. 1J are schematic diagrams of a plurality of semiconductor packages according to other embodiments of the invention.

Referring to FIG. 1G and FIG. 1H, a main difference between the semiconductor package 100a of FIG. 1G, the semiconductor package 100b of FIG. 1H and the semiconductor package 100 of the previous embodiment lies in the form of the weldments 160. In FIG. 1F, the weldments 160 are, for example, solder balls 162. In FIG. 1G, the weldments 160 are, for example, solder caps 164. In FIG. 1H, the weldments 160 are, for example, solder layers 166. Certainly, the above merely listed some of the forms of the weldments 160 as examples; in fact, the foul's of the weldments 160 are not limited thereto.

Referring to FIG. 1I, a main difference between the semiconductor package 100c of FIG. 1I and the semiconductor package 100 of FIG. 1F lies in that, in the present embodiment, the chip backside 128 of the second chip 120 is exposed out of the molded underfill 152. That is, during the process of manufacturing the semiconductor package 100c of the present embodiment, when performing the grinding process to the molded underfill 152, the molded underfill 152 is grinded to a state of being exposed out of the chip backside 128. Therefore, after the grinding process, the first conductive bumps 130 are aligned with the chip backside 128 of the second chip 120.

Referring to FIG. 1J, a main difference between the semiconductor package 100d of FIG. 1J and the semiconductor package 100 of FIG. 1F lies in that, in the present embodiment, the underfill 150 further includes an inner underfill 154, wherein the inner underfill 154 is located between the chip bonding zone 114 of the first chip 110 and the second chip 120, the inner underfill 154 fills in the opening of the protective layer 170, and the molded underfill 152 covers the inner underfill 154. The material of the inner underfill 154 can be the same or different from that of the molded underfill 152. The semiconductor package 100d of the present embodiment protects the second conductive bumps 140 by firstly using the inner underfill 154 to fill between the chip bonding zone 114 of the first chip 110 and the second chip 120; and then, with the two-stage packaging of using the molded underfill 152 to cover the second chip 120 and the first conductive bumps 130, the semiconductor package 100d further provides a favorable structure strength.

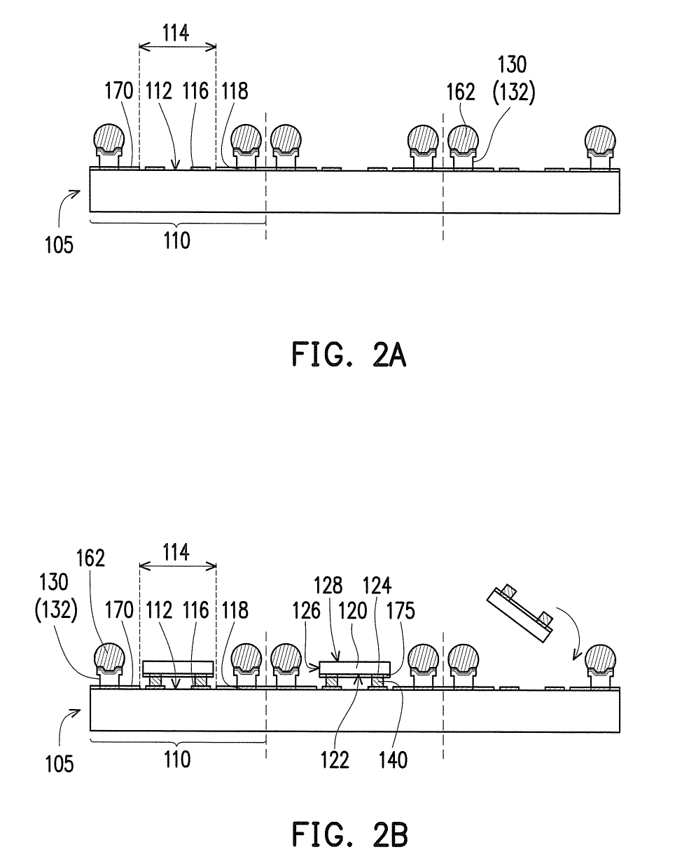

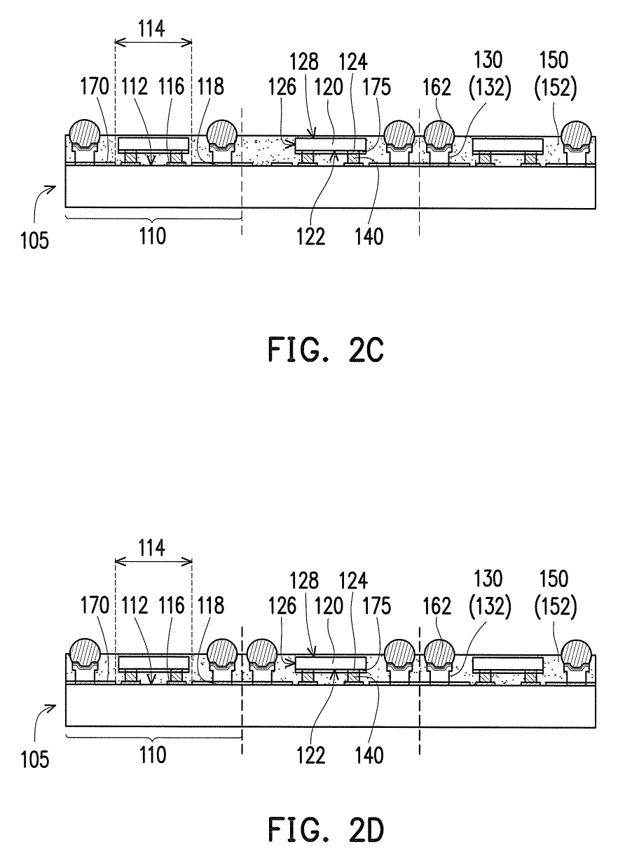

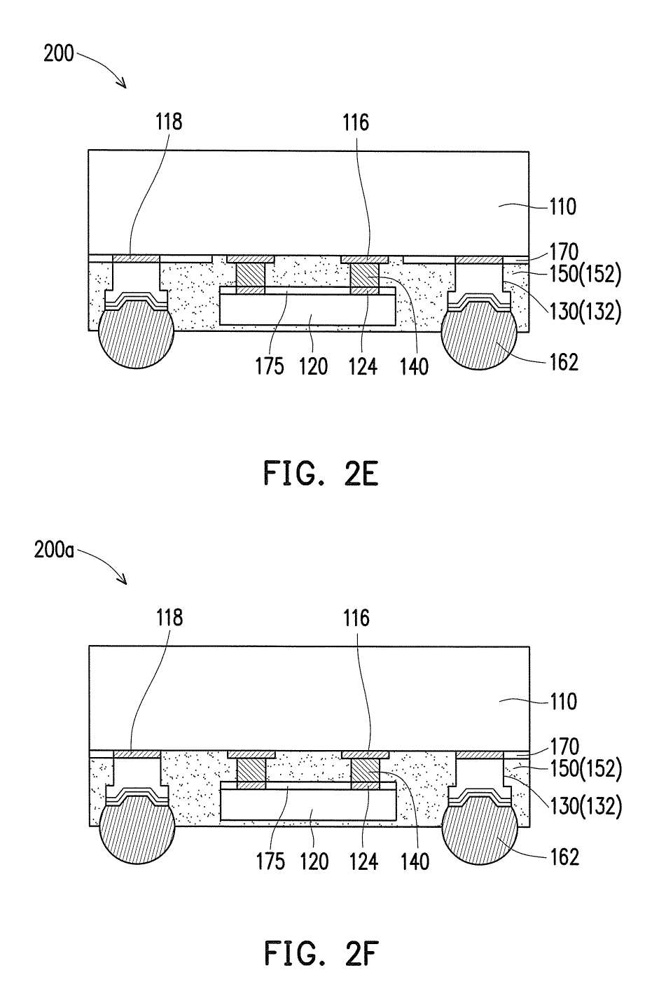

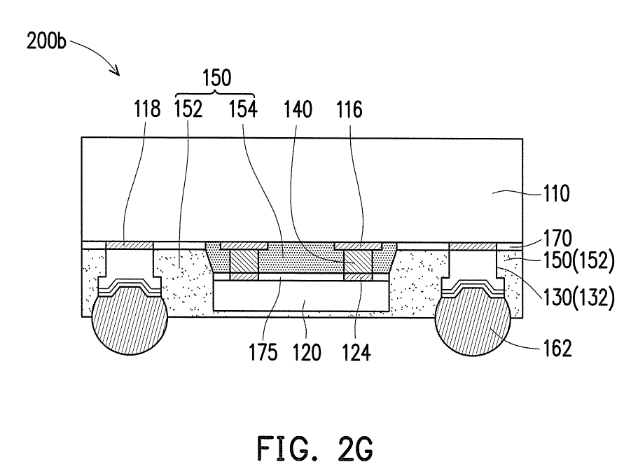

Another manufacturing process of the semiconductor package is provided in below. FIG. 2A to FIG. 2E are schematic manufacturing flow diagrams of the semiconductor package 100 according to another embodiment of the invention. The semiconductor package manufacturing method of the present embodiment includes the following steps.

Firstly, referring to FIG. 2A, a wafer 105 including a plurality of first chips 110 arranged in an array is provided, wherein each of the first chips 110 includes a first active surface 112, the first active surface 112 includes a chip bonding zone 114, a plurality of first inner pads 116 in the chip bonding zone 114 and a plurality of first outer pads 118 out of the chip bonding zone 114, the first active surface 112 is disposed with a protective layer 170 thereon, the protective layer 170 includes an opening at least corresponding to the chip bonding zone 114, and the first inner pads 116 and the first outer pads 118 are exposed out of the protective layer 170.

Next, a deposition process of an under bump metal (UBM) layer 132 is performed. In the present embodiment, oxides on the first outer pads 118 are removed with argon gas. Next, a titanium-tungsten layer and a gold layer or a titanium layer and a copper layer are sequentially sputtered on the first outer pads 118, and then gold, copper, or copper/nickel/gold, etc. are electroplated to form the under bump metal layers 132 on the first outer pads 118. Next, a plurality of solder balls 162 are disposed on the under bump metal layers 132 of the first outer pads 118 to electrically connect with the first outer pads 118.

Further, referring to FIG. 2B, a plurality of second chips 120 with smaller size are flipped on the chip bonding zones 114 of the first chips 110, wherein each of the second chips 120 includes a second active surface 122, a plurality of second chip side faces 126 connected to the second active surface 122 and a chip backside 128 opposite to the second active surface 122. Each of the second active surfaces 122 includes a plurality of second pads 124, each of the second active surfaces 122 faces towards the first active surface 112 and the second pads 124 are electrically connected to the first inner pads 116.

Next, referring to FIG. 2C, a molded underfill process is performed to form an underfill 150 on the first active surface 112. In the present embodiment, the underfill 150 is a molded underfill 152, wherein the molded underfill 152 covers the second chips 120, the under bump metal layers 132 and a part of each of the solder balls 162 to complete a plurality of semiconductor packages 200. Finally, referring to FIG. 2D, a cutting process is performed to separate the semiconductor packages 200 from each other.

Referring to FIG. 2E, the semiconductor package 200 of the present embodiment includes a first chip 110, a second chip 120, a plurality of first conductive bumps 130 (each of the first conductive bumps 130 being an under bump metal layer 132), a plurality of second conductive bumps 140, an underfill 150 (the molded underfill 152), a plurality of weldments 160 and a protective layer 170. The first chip 110 includes a first active surface 112, wherein the first active surface 112 includes a chip bonding zone 114, a plurality of first inner pads 116 in the chip bonding zone 114 and a plurality of first outer pads 118 out of the chip bonding zone 114. The protective layer 170 is disposed on the first active surface 112 of the first chip 110, the first inner pads 116 and the first outer pads 118 are exposed out of the protective layer 170, and the protective layer 170 includes an opening corresponding to the chip bonding zone 114.

The second chip 120 is flipped on the chip bonding zone 114 of the first chip 110, and includes a second active surface 122 and a plurality of second chip side faces 126 connected to the second active surface 122, wherein the second active surface 122 includes a plurality of second pads 124. The under bump metal layers 132 are disposed on the first outer pads 118. The second conductive bumps 140 are located between the first inner pads 116 and the second pads 124, and each of the first inner pads 116 is electrically connected with the corresponding second pad 124 via the corresponding second conductive bump 140.

The molded underfill 152 is located on the first active surface 112, and covers the second conductive bumps 140, each of the second chip side faces 126, each of the under bump metal layers 132 and a part of each of the solder balls 162. In the present embodiment, a distance from the chip backside 128 of the second chip 120 to the first inner pads 116 is greater than a height of the under bump metal layers 132, and a height of each of the under bump metal layers 132 is greater than a distance between the first active surface 112 and the second active surface 122. Moreover, in the present embodiment, each of the solder ball 162 protrudes out of the molded underfill 152 by a height ranges from 0.5 to 0.8 times of a height of the solder ball 162, and the aforesaid range enables the molded underfill 152 to have certain fixing effect on the solder ball 162 and does not affect the subsequent connection between the solder ball 162 and the circuit board (not shown). In the semiconductor package 100 of the present embodiment, in addition to the second chip 120 being encapsulated by the molded underfill 152, a part of the solder ball 162 is also encapsulated by the molded underfill 152, and thereby effectively increases the overall structural strength.

Other semiconductor packages 200a, 200b are continued to be disclosed below. FIG. 2F to FIG. 2G are schematic diagrams of a plurality of semiconductor packages according to other embodiments of the invention. Referring to FIG. 2F, a main difference between the semiconductor package 200a of FIG. 2F and the semiconductor package 200 of FIG. 2E lies in the position of the protective layer 170 on the first chip 110. In FIG. 2E, a portion of the protective layer 170 is located between two of the first outer pads 118, and the opening of the protective layer 170 is substantially corresponded to the chip bonding zone 114 (as marked in FIG. 2D). In FIG. 2F, the protective layer 170 is only located outside of two of the first outer pads 118, that is, the region of the opening of the protective layer 170 is closes to the region surrounded by the first outer pads 118.

Referring to FIG. 2G, a main difference between the semiconductor package 200b of FIG. 2G and the semiconductor package 200 of FIG. 2E lies in that, in the present embodiment, the underfill 150 further includes an inner underfill 154, wherein the inner underfill 154 is located between the chip bonding zone 114 of the first chip 110 and the second chip 120, and the molded underfill 152 covers the inner underfill 154. The material of the inner underfill 154 can be the same or different from that of the molded underfill 152. The semiconductor package 200b of the present embodiment protects the second conductive bumps 140 by firstly using the inner underfill 154 to fill between the chip bonding zone 114 of the first chip 110 and the second chip 120; and then, with the two-stage packaging of using the molded underfill 152 to cover the second chip 120, the under bump metal layers 132 and a part of each of the solder ball 162, the semiconductor package 200b further provides a favorable structure strength.

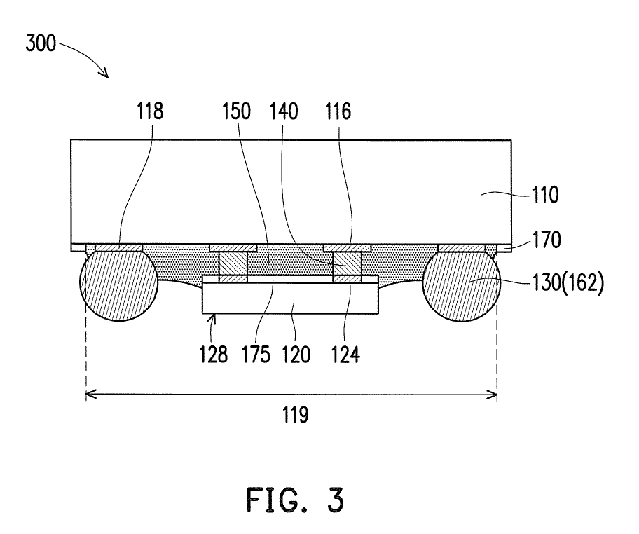

FIG. 3 is a schematic diagram of a semiconductor package according to an embodiment of the invention. Referring to FIG. 3, a main difference between the semiconductor package 300 of FIG. 3 and the semiconductor package 200 of FIG. 2E lies in that, in the present embodiment, the protective layer 170 is disposed in a region outside of a virtual area 119 surrounded by the first outer pads 118 on the first active surface 112 of the first chip 110. The underfill 150 covers a part of each of the second chip side faces 126 of the second chip and a part of each of the first conductive bumps 130 (solder balls 162) by means of filling gel so as to completely cover bonding sites between the first outer pads 118 and the first conductive bumps 130, and ends at the edges of the protective layer 170. The semiconductor package 300 of the present embodiment covers a part of each of the second chip side faces 126 of the second chip 120 and a part of each of the solder balls 162 via the underfill 150 so as to enhance the overall structure strength of the semiconductor package 300.

In summary, the underfill of the semiconductor package of the invention covers the second conductive bumps, at least a part of each of the second chip side faces and at least a part of each of the first conductive bumps to increase an overall structural strength. Therefore, the semiconductor package of the invention can have the lower chipping rate. In addition, the invention further provides multiple semiconductor package manufacturing methods for producing the aforementioned semiconductor package.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor package, comprising:
a first chip, comprising a first active surface, wherein the first active surface comprises a chip bonding zone, a plurality of first inner pads in the chip bonding zone and a plurality of first outer pads out of the chip bonding zone;
a second chip, flipping on the chip bonding zone of the first chip, and comprising a second active surface and a plurality of second chip side faces connected to the second active surface, wherein the second active surface comprises a plurality of second pads;
a plurality of first conductive bumps, disposed on the first outer pads;
a plurality of second conductive bumps, located between the first inner pads and the second pads, each of the first inner pads being electrically connected with the corresponding second pad via the correspondingly second conductive bump;
an underfill, disposed on the first active surface, and covering the second conductive bumps, at least a part of each of the second chip side faces and at least a part of each of the first conductive bumps, wherein the underfill comprises a molded underfill (MUF), and the molded underfill covers all the second chip side faces;
a plurality of solder balls, disposed on the first conductive bumps, each of the first conductive bumps being an under bump metal (UBM) layer, and the molded underfill covering only a part of each of the solder balls; and
a protective layer, disposed on the first active surface of the first chip, the protective layer comprising an opening at least corresponding to the chip bonding zone, and the first inner pads and the first outer pads being exposed out of the protective layer.

2. (canceled)

3. The semiconductor package as recited in claim 1, wherein the second chip further comprises a chip backside opposite to the second active surface, and the chip backside is covered by the molded underfill or the chip backside is exposed by the molded underfill.

4. The semiconductor package as recited in claim 1, further comprising:
a plurality of weldments, the first conductive bumps being exposed out of the molded underfill, and the weldments being disposed on the molded underfill and connected to the first conductive bumps, wherein each of the weldments comprises a solder ball, a solder cap or a solder layer.

5-6. (canceled)

7. The semiconductor package as recited in claim 1, wherein the second chip further comprises a chip backside opposite to the second active surface, a distance from the chip backside of the second chip to the first inner pads is greater than a height of each of the first conductive bumps, and the height of each of the first conductive bumps is greater than a height of each of the second conductive bumps.

8. The semiconductor package as recited in claim 1, wherein each of the solder balls protrudes out of the molded underfill by a height ranging from 0.5 to 0.8 times of a height of the solder ball.

9. The semiconductor package as recited in claim 1, further comprising:
a protective layer, disposed on the first active surface of the first chip, wherein the first inner pads and the first outer pads are exposed out of the protective layer, the protective layer comprises an opening corresponding to the chip bonding zone, the underfill comprises an inner underfill, the inner underfill is located between the chip bonding zone of the first chip and the second chip, and the molded underfill covers the inner underfill.

10. The semiconductor package as recited in claim 1, further comprising:
a protective layer, disposed in a region outside of a virtual area surrounded by the first outer pads on the first active surface of the first chip, wherein the underfill covers a part of each of the second chip side faces of the second chip and a part of each of the first conductive bumps, and each of the first conductive bumps is a solder ball.

11-14. (canceled)

15. A semiconductor package manufacturing method, comprising:
providing a wafer comprising a plurality of first chips arranged in an array, wherein each of the first chips comprises a first active surface, the first active surface comprises a chip bonding zone, a plurality of first inner pads in the chip bonding zone and a plurality of first outer pads out of the chip bonding zone, the first active surface is disposed with a protective layer thereon, the protective layer comprises an opening at least corresponding to the chip bonding zone, and the first inner pads and the first outer pads are exposed out of the protective layer;
disposing a plurality of solder balls on the first outer pads to electrically connect with the first outer pads;
flipping a plurality of second chips on the chip bonding zones of the first chips, wherein each of the second chips comprises a second active surface and a plurality of second chip side faces connected to the second active surface, each of the second active surfaces comprises a plurality of second pads, each of the second active surface faces toward the first active surface, and the second pads are electrically connected to the first inner pads;
performing a molded underfill process to form a molded underfill on the first active surface, wherein the molded underfill covers the second chip and a part of each of the solder balls to complete a plurality of semiconductor packages, and the molded underfill covering only a part of each of the solder balls; and
performing a cutting process to separate the semiconductor packages from each other.

16. The semiconductor package manufacturing method as recited in claim 15, wherein the solder balls and the first outer pads have a plurality of under bump metal (UBM) layers disposed therebetween, and the molded underfill covers the under bump metal layers.

17. The semiconductor package manufacturing method as recited in claim 16, wherein the second chip further comprises a chip backside opposite to the second active surface, a distance from the chip backside of the second chip to the first inner pads is greater than a height of each of the under bump metal layers, and the height of each of the under bump metal layers is greater than a distance between the first active surface and the second active surface.

18. The semiconductor package manufacturing method as recited in claim 15, wherein each of the solder balls protrudes out of the molded underfill by a height ranging from 0.5 to 0.8 times of a height of the solder ball.

19. The semiconductor package manufacturing method as recited in claim 15, after flipping on the second chip and before performing the molded underfill process, further comprising:
disposing an inner underfill between the chip bonding zone of the first chip and the second chip, wherein, after performing the molded underfill process, the molded underfill covers the inner underfill.

20. The semiconductor package manufacturing method as recited in claim 15, wherein the protective layer is located in a region outside of a virtual area surrounded by the first outer pads on the first active surface of the first chip, the molded underfill covers a part of each of the second chip side faces of the second chip and a part of each of a plurality of first conductive bumps, and each of the first conductive bumps is a solder ball.
